(19) United States
(12) Patent Application Publication
(10) Pub. No.: US 2007/0170848 A1
(43) Pub. Date: Jul. 26, 2007

(54) METHOD OF MANUFACTURING DUAL EMISSION DISPLAY AND DUAL EMISSION DISPLAY MANUFACTURED THEREBY

(75) Inventors: Hsiang-Chiu Wu, Miaoli County (TW); Shi-Hao Li, Taipei County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu (TW)

(21) Appl. No.: 11/456,593

(22) Filed: Jul. 11, 2006

(30) Foreign Application Priority Data
Jan. 26, 2006 (TW) 95103046

(51) Int. Cl. H05B 33/00; H01J 1/62

(52) U.S. Cl. 313/506; 313/504

(57) ABSTRACT

A dual emission display and a method of manufacturing a dual emission display are provided. The method comprises providing a substrate having a first region and a second region, forming a light shielding layer on the second region, forming a controlling device on the light shielding layer, forming an organic emitting device electrically connected to the controlling device, thereby completing a first display device. The first display device and a second display device, obtained by repeating the above procedures, are oppositely disposed and packaged to complete the dual emission display.

### BACKGROUND OF THE INVENTION

1. Field of the Invention

The invention relates to a method of manufacturing dual emission displays, and more particularly to a method of manufacturing dual emission displays with reduced thickness.

2. Description of the Related Art

Recently, with the development and wide application of electronic products, such as mobile phones, PDA, and notebook computers, increasing demand for flat display elements which consume less electric power and occupy less space was increased. Among flat panel displays, organic electroluminescent devices are self-emitting, and highly luminous, with wider viewing angle, faster response, and a simple fabrication process, making them the industry display of choice.

An organic light-emitting diode (OLED) is an increasingly popular light-emitting diode that uses an organic electroluminescent layer. According to the direction from which the light is obtained, organic electroluminescent elements are classified as bottom-emission, top-emission, or dual emission organic electroluminescent devices.

Contrast in bottom-emission, top-emission, or dual emission organic electroluminescent devices, suffers due to reflection of environmental light (such as sunlight), thereby deteriorating performance. In order to reduce the glare from reflected light, the organic electroluminescent devices have incorporated a single-layer or multi-layer optical element such as a polarizer, an optical compensation film, or combinations thereof. The aforementioned method, however, has increased process complexity and cost, and causes the increase of thickness of organic electroluminescent devices.

In a conventional dual emission organic electroluminescent device, the organic light-emitting diodes thereof are disposed on the same substrate and achieve simultaneous dual emission by means of transparent electrodes or specific designs. The conventional dual emission organic electroluminescent device, however, has a low aperture ratio for each side and increased process complexity.

### BRIEF SUMMARY OF THE INVENTION

Dual emission devices are provided. An exemplary embodiment of a dual emission device comprises a first display device and a second display device, parallel and opposite to each other, wherein each of the first and second display device comprises: a substrate with a first region and second region; an anti-reflection layer formed on the second region; a controlling element on the anti-reflection layer; and an organic light-emitting element formed on the first region electrically connected to the controlling element, wherein the first and second display devices have opposite emission directions.

Methods of manufacturing dual emission devices are also provided. An exemplary embodiment of a method comprises the following steps: (a) providing a substrate with a first region and a second region; (b) forming an anti-reflection layer on the second region; (c) forming a controlling element on the anti-reflection layer; (d) forming an organic light-emitting element on the first region, electrically connected to the controlling element, thereby completing a first display device; (e) repeating the steps (a)˜(d) to obtain a second display device; (f) combining the first display device and second display device, resulting in that the first and second display devices have opposite emission directions; and (g) packaging the first display device and second display device to obtain the dual emission device.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1a˜1c show cross sections of the process of manufacturing a display device of a dual emission device according to an embodiment of the invention; and;

FIG. 2 shows a cross section of the dual emission device according to an embodiment of the invention.

### DETAILED DESCRIPTION OF THE INVENTION

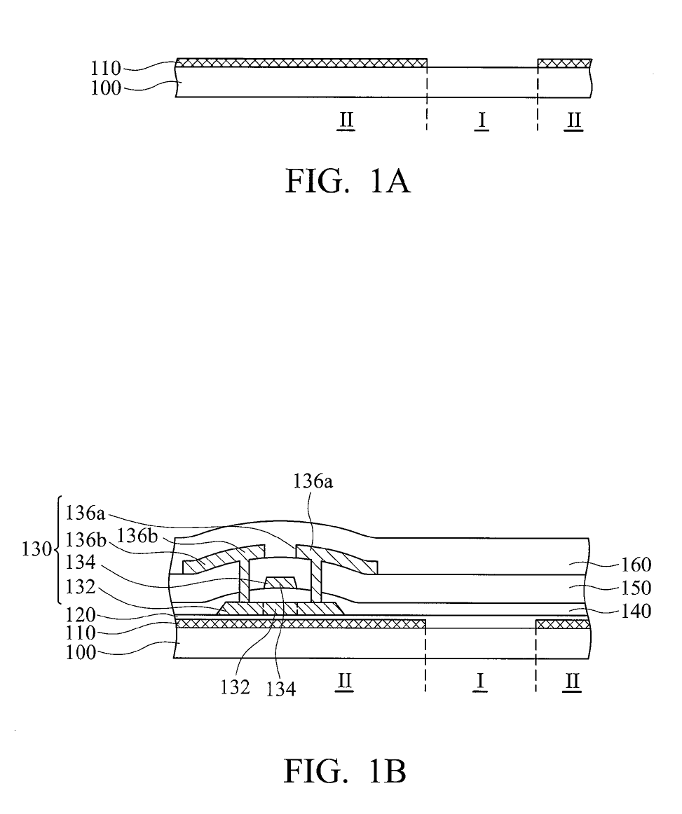

FIGS. 1a-1c show cross sections of an exemplary embodiment of a process for manufacturing a display device of dual emission device.

Referring to FIG. 1a, a transparent substrate 100 is provided, wherein the transparent substrate 100 is predefined as a first region I (emission region) and a second region II (non-emission region). A patterned anti-reflection layer 110 is formed on the second region II of the substrate 100. The method of forming the anti-reflection layer 110 can comprise the following steps. First, an anti-reflection layer is blanketly formed on the substrate 100. Next, the anti-reflection layer is patterned by photolithography to completely remove the anti-reflection layer from the first region I, thereby leaving the patterned anti-reflection layer within the second region II. Suitable material of the anti-reflection layer can be chromium or chromium-containing compound, such as chromium oxide, chromium nitride, or combinations thereof. Further, the anti-reflection layer can be metal-containing complex, such as organic or inorganic complexes. The patterned anti-reflection layer 110 can comprise opaque components and serve as a black matrix. Further, the anti-reflection layer 110 can be a part of a black matrix layer, wherein the anti-reflection layer 110 directly physically contacts the substrate 100. The anti-reflection layer can be formed by physical deposition or chemical vapor deposition and have a thickness of 500˜2500 Å.

Referring to FIG. 1b, a buffer layer 120 is formed on the substrate 100, covering the patterned anti-reflection layer 110. Next, a controlling element 130 is formed on the anti-reflection layer 110 within the second region II. The buffer layer can comprise oxide. The controlling element 130 can be an active component, such as a thin film transistor, comprising a semiconductor layer 132, a gate electrode 134, and source/drain electrodes 136a and 136b. Further, a first dielectric layer 140 is formed between the semiconductor layer 132 and the gate electrode 134, a second dielectric layer 150 is formed between the gate electrode 134 and source/drain electrodes 136a and 136b, and a third dielectric layer 160 formed to cover the controlling element 130. Wherein, the first, second and third dielectric layers 140, 150, and 160 can be organic or inorganic material, such as silicon oxide, or silicon nitride.

Referring to FIG. 1c, a light-emitting element, such as an organic light-emitting element 170, is formed on the third dielectric layer 160 at least within the first region I. In an embodiment of the invention, the light-emitting element can be a polymer light-emitting element. Herein, the organic light-emitting element 170 comprises a first electrode 172, a second electrode 176, and electroluminescent layers 174 therebetween. In general, the electroluminescent layers 174 can comprise a plurality of layers such as a hole injection layer, a hole transport layer, a light-emitting layer, an electron transport layer, or an electron injection layer. Further, the electroluminescent layers 174 can also comprise multifunctional layers substituting for the hole injection layer, hole transport layer, light-emitting layer, or electron transport layer. The structure of the electroluminescent layer 174 is illustrated an example, and is not intended to be limitative of the invention.

The first electrode 172 of the light-emitting element 170 is electrically connected to one of the source/drain electrodes 136a and 136b through a via hole passing through the third dielectric layer 160, thus completing the fabrication of a display device of the dual emission device. Noted that the first electrode 172 comprises transparent metal or metal oxide, such as indium tin oxide (ITO), indium zinc oxide (IZO), aluminum zinc oxide (AZO), or zinc oxide (ZnO). The second electrode 176 can be a transparent electrode such as ITO or opaque electrode such as Al.

Furthermore, a desiccant layer 200 is formed on the light-emitting element 170 by PECVD. Wherein, the desiccant layer 200 can be calcium, calcium oxide, or a combination thereof. In some embodiments of the invention, a protection layer can be optionally formed on the light-emitting element 170.

Specifically, a plurality of the previously described display devices can be simultaneously fabricated on the same substrate and separated by cutting. Namely, at least two display devices having the same structure can be obtained simultaneously.

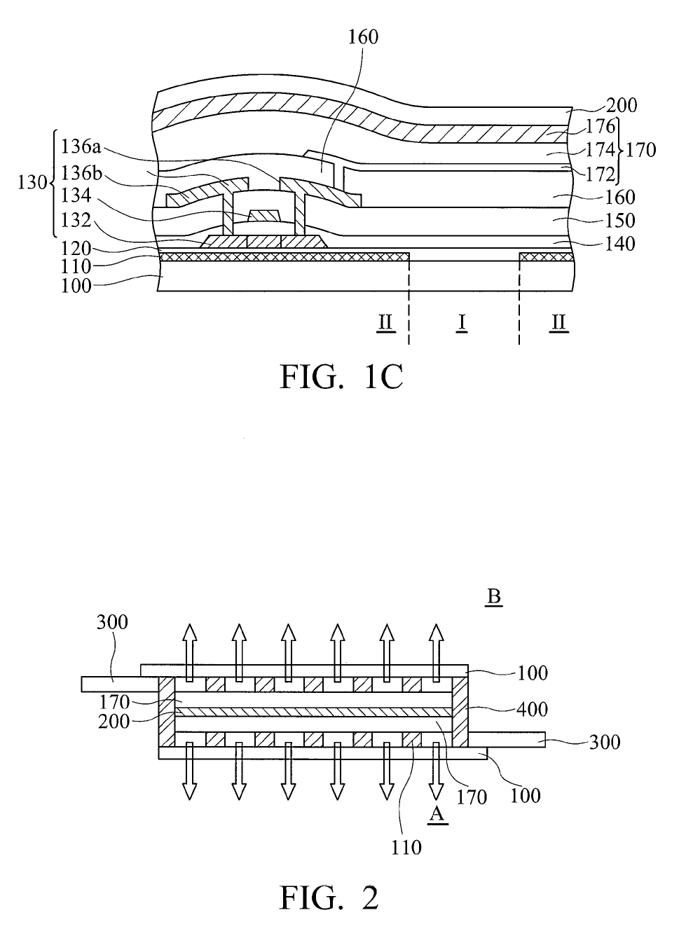

In one embodiment of invention, a first display device and a second display device are disposed in parallel and opposite to each other. An encapsulant 400 is used to combine and package the first display device and the second display device. Note that the first emission direction A of the first display device is opposite to the second emission direction B of the second display device, referring to FIG. 2. Wherein, the first display device and the second display device can have the same structure and be formed by the same process. The first display device and the second display device can also have different structures.

In another embodiment of the invention, the first and second display devices can omit the desiccant layer 200, and a desiccant can be disposed between the first and second display devices. Furthermore, in some embodiment of the invention, at least one of the first and second display devices has a desiccant layer formed on the light-emitting element 170, referring to FIG. 2. In general, referring to FIG. 2, a flexible printed circuit 300 can be used to electrically connect to pads of the peripheral circuit of the first and second display devices.

Accordingly, due to the disposition of the anti-reflection layer (500˜2500 Å), the dual emission device of the invention offers improved contrast, without requiring a polarizer (having a thickness of more than 0.5 mm) to be formed on the outer surface thereof. Thus, the dual emission device can have a thickness of less than 2.0 mm, and the cost of dual emission device is also reduced. Moreover, since the anti-reflection layer is formed on the second region II (non-emission), the brightness of the display devices would not be declined by the anti-reflection layer. To the contrary, the conventional dual emission device has reduced brightness due to the polarizer, and a greater power must to be applied to maintain a specific brightness, resulting in shorter product life. Therefore, the dual emission device has lower thickness, improved contrast, and longer life-time in comparison with the conventional dual emission device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a dual emission device, comprising:
(a) providing a substrate with a first region and a second region;
(b) forming an anti-reflection layer on the second region;
(c) forming a controlling element on the anti-reflection layer;
(d) forming an organic light-emitting element on the first region, electrically connected to the controlling element, thereby completing a first display device;
(e) repeating the steps (a)˜(d) to obtain a second display device;
(f) combining the first display device and second display device, resulting in the first and second display devices having opposite emission directions; and
(g) packaging the first display device and second display device, obtaining the dual emission device.

2. The method as claimed in claim 1, further comprising:
forming a desiccant layer between the first and second display devices prior to packaging the first display device and second display device.

3. The method as claimed in claim 1, further comprising:
disposing a desiccant between the first and second display devices prior to packaging the first display device and second display device.

4. The method as claimed in claim 1, wherein forming the anti-reflection layer comprises forming a black matrix on the second region.

5. The method as claimed in claim 1, wherein the anti-reflection layer comprises chromium, chromium-containing compound, or a combination thereof.

6. The method as claimed in claim 1, wherein the anti-reflection layer comprises organic or inorganic complexes.

7. The method as claimed in claim 1, wherein the anti-reflection layer has a thickness of about 500 Å to about 2500 Å.

8. The method as claimed in claim 1, wherein the anti-reflection layer is formed by physical deposition or chemical vapor deposition.

9. The method as claimed in claim 1, wherein the method of forming the first display device and the second display device further comprises:
forming a protection layer on the organic light-emitting element.

10. The method as claimed in claim 1, wherein the first display device and the second display device have the same structure.

11. The method as claimed in claim 1, wherein the first display device and the second display device are formed by the same process.

12. The method as claimed in claim 1, before forming the controlling element on the anti-reflection layer, further comprising:
forming a buffer layer on the anti-reflection layer.

13. A dual emission device, comprising:
a first display device and a second display device, parallel and opposite each other, wherein each of the first and second display device comprises
a substrate with a first region and second region;
an anti-reflection layer formed on the second region;
a controlling element on the anti-reflection layer; and
an organic light-emitting element formed on the first region electrically connected to the controlling element,
wherein the first and second display devices have opposite emission directions.

14. The device as claimed in claim 13, wherein the anti-reflection layer comprises a black matrix layer.

15. The device as claimed in claim 13, wherein the anti-reflection layer comprises chromium, chromium-containing compound, or a combination thereof.

16. The device as claimed in claim 13, wherein the anti-reflection layer comprises organic or inorganic complexes.

17. The device as claimed in claim 13, wherein each of the first and second display devices further comprises a protection layer on the organic light-emitting element.

18. The device as claimed in claim 13, further comprising a desiccant layer between the first and second display devices.

19. The device as claimed in claim 13, wherein the anti-reflection layer has a thickness of about 500 Å to about 2500 Å.

20. The device as claimed in claim 13, wherein the dual emission device has a thickness of less than 2.0 mm.

21. The device as claimed in claim 13, wherein each of the first and second display devices further comprises a buffer layer on the anti-reflection layer.
